(19) United States
(12) Patent Application Publication
(10) Pub. No.: US 2021/0131652 A1
(43) Pub. Date: May 6, 2021

(54) FLEXIBLE LIGHT EMITTING SYSTEM

(71) Applicant: MAGNA INTERNATIONAL INC., Aurora (CA)

(72) Inventors: Ronald S. ZAK, Rochester Hills, MI (US); Todd DEAVILLE, Markham (CA)

(21) Appl. No.: 16/639,577

(22) PCT Filed: Aug. 14, 2018
(86) PCT No.: PCT/US2018/046684

§ 371 Date: Feb. 16, 2020

Related U.S. Application Data
(60) Provisional application No. 62/547,587, filed on Aug. 18, 2017.

(51) Int. Cl. F21V 23/00; H05K 1/18

(52) U.S. Cl. CPC F21V 23/005; F21Y 2105/16; H05K 1/189

(57) ABSTRACT

A flexible light emitting system is provided and includes a flexible printed circuit layer that has a substrate with a top in surface and a bottom surface and a plurality of traces of silver paste disposed on the top surface. A plurality of micro light emitting diodes are disposed on the top surface and soldered to the plurality of traces to provide light. An elastic interlayer film of ethylene vinyl acetate copolymer extends over the top surface of the flexible printed circuit layer for protection of the plurality of micro light emitting diodes and the plurality of traces. A diffuser layer extends over the elastic interlayer film opposite the flexible printed circuit layer to diffuse the light from the plurality of micro light emitting diodes. An optically transparent material layer extends between the elastic interlayer film and the diffuser layer to provide a uniform light appearance.

### CROSS REFERENCE TO RELATED APPLICATION

This PCT International Patent Application claims the benefit of U.S. Provisional Patent Application Ser. No. 62/547,587 filed Aug. 18, 2017 entitled “Flexible Light Emitting System,” the entire disclosure of the application being considered part of the disclosure of this application and hereby incorporated by reference.

### FIELD

The present disclosure relates generally to a flexible light emitting system.

### BACKGROUND

This section provides background information related to the present disclosure which is not necessarily prior art.

Organic light-emitting diode (OLED) lighting systems are commonly used in various applications including automotive lighting and displays, televisions, and portable electronic devices. Known lighting systems may also use panels with light-emitting diodes (LEDs) disposed along the edges of the panel or side emitting LEDs. While OLED lighting systems and side-lit panels can provide high contrast displays and lighting panels that do not take up much space, such lighting systems may produce non-uniform light distribution, are less robust, and are commonly expensive or complicated to produce.

Thus, there is an increasing need for improved light emitting systems that create a uniform light stack that can be used to provide lighting for various applications, such as interior and exterior automotive applications.

### SUMMARY

This section provides a general summary of the present disclosure and is not intended to be interpreted as a comprehensive disclosure of its full scope or all of its features, aspects and objectives.

Accordingly, it is an aspect of the present disclosure to provide a flexible light emitting system that includes a flexible printed circuit layer that has a substrate with a top surface and a bottom surface. The flexible printed circuit layer also includes a plurality of traces disposed on the top surface. The flexible printed circuit layer includes a plurality of micro light emitting diodes disposed on the top surface and electrically coupled to the plurality of traces to provide light. An elastic interlayer film extends over the top surface of the flexible printed circuit layer for protection of the plurality of micro light emitting diodes and the plurality of traces. A diffuser layer extends over the elastic interlayer film opposite the flexible printed circuit layer to diffuse the light from the plurality of micro light emitting diodes.

This and other aspects and areas of applicability will become apparent from the description provided herein. The description and specific examples in this summary are intended for purpose of illustration only and are not intended to limit the scope of the present disclosure.

### DRAWINGS

The drawings described herein are for illustrative purposes only of selected embodiments and not all implementations, and are not intended to limit the present disclosure to only that actually shown. With this in mind, various features and advantages of example embodiments of the present disclosure will become apparent from the following written description when considered in combination with the appended drawings, in which:

FIG. 1 is an exploded cross-sectional view of a first exemplary embodiment of a light emitting system according to aspects of the disclosure; and

FIG. 2 is an exploded cross-sectional view of a second exemplary embodiment of a light emitting system according to aspects of the disclosure.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to a flexible light emitting system of the type well-suited for use in many applications. More specifically, a flexible light emitting system that creates a uniform light stack that can be used to provide lighting for various applications, such as interior and exterior automotive lighting applications. The flexible light emitting system of this disclosure will be described in conjunction with one or more example embodiments. However, the specific example embodiments disclosed are merely provided to describe the inventive concepts, features, advantages and objectives will sufficient clarity to permit those skilled in this art to understand and practice the disclosure.

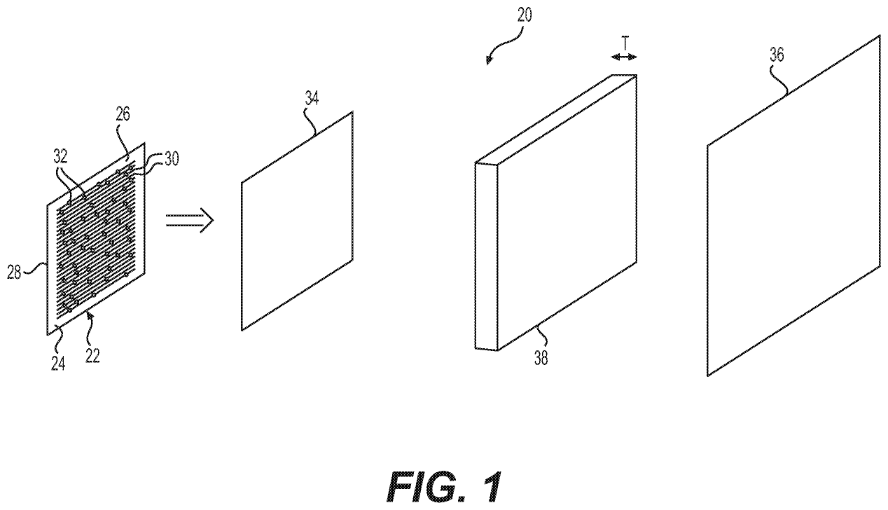

A first exemplary embodiment of the flexible light emitting system 20 is shown in FIG. 1 and includes a flexible printed circuit (FPC) layer 22 that has a base material or substrate 24 that is flexible, rather than being rigid and has a top surface 26 and a bottom surface 28. The flexible printed circuit layer 22 includes a plurality of traces 30 disposed on the top surface 26. The plurality of traces 30 comprise a silver paste or printed silver circuitry; however, it should be appreciated that the plurality of traces 30 could instead comprise nano copper traces or other conductive materials. The substrate 24 comprises a polyethylene terephthalate (PET) film. Yet, other flexible substrate materials, such as, but not limited to polyimide, polyester film, and polyether ether ketone (PEEK) may alternatively be used. The flexible printed circuit layer 22 may also be separately laminated.

The flexible printed circuit layer 22 includes a plurality of micro light emitting diodes 32 (LEDs) disposed on the top surface 26 and soldered (or otherwise electrically coupled) to the plurality of traces 30 to provide light. Specifically, the micro plurality of light emitting diodes 32 may be different colors, including red micro LEDs, blue micro LEDs and amber micro LEDs. Phosphor can additionally be added to the plurality of micro light emitting diodes 32. For example, blue micro LEDs with phosphor emit white light.

An elastic interlayer film 34 extends over the top surface 26 of the flexible printed circuit layer 22 for protection of the plurality of micro light emitting diodes 32 and the plurality of traces 30. The elastic interlayer film 34 can, for example, comprise ethylene-vinyl acetate (EVA) copolymer (e.g., Evguard® film) or other suitable film that is elastic for protecting the plurality of micro light emitting diodes 32 and the plurality of traces 30.

A diffuser layer 36 extends over the elastic interlayer film 34 opposite the flexible printed circuit layer 22 to diffuse the light from the plurality of micro light emitting diodes 32. The diffuser layer 36 is also adapted to be printed upon to provide an eye pleasing unlit appearance. An optically transparent material layer 38 extends between the elastic interlayer film 34 and the diffuser layer 36 and has a thickness T to provide a uniform light appearance from the plurality of micro light emitting diodes 32. In more detail, the optically transparent material layer 38 is watertight and ultraviolet (UV) stable and is optically transparent to allow light to be transmitted through the optically transparent material layer 38. The primary role of the optically transparent material layer 38 is to provide a spacing or distance between the elastic interlayer film 34 and the diffuser layer 36, so that the appearance of the light coming from the plurality of micro light emitting diodes 32 is made uniform, thus various transparent materials may be utilized. Preferably, the thickness T of the optically transparent material layer 38 is 2-10 mm; however, the thickness T can be varied depending on the specific application of the flexible light emitting system 20 and desired diffusion.

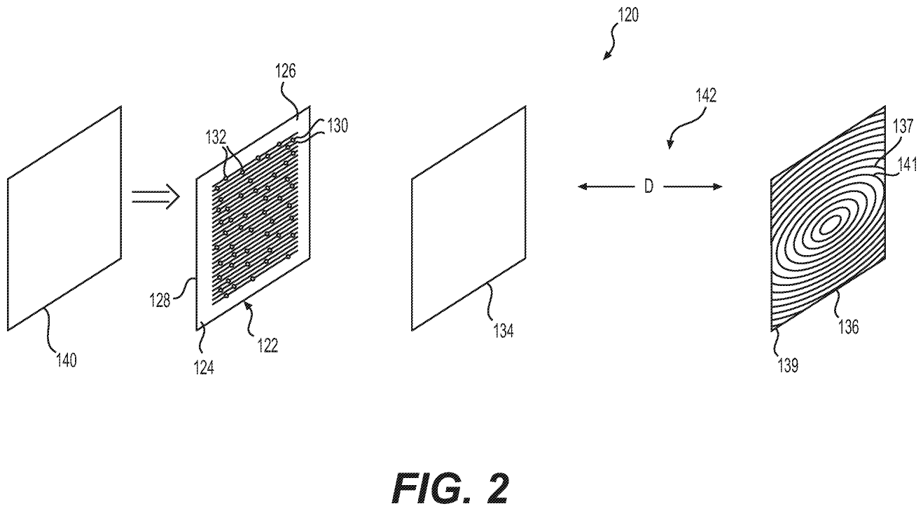

A second exemplary embodiment of the flexible light emitting system 120 is shown in FIG. 2 with like numerals separated by a factor of 100, being used to show features corresponding to the first exemplary embodiment discussed above. The second exemplary embodiment of the flexible light emitting system 120 also includes a flexible printed circuit layer 122 that has a substrate 124 with a top surface 126 and a bottom surface 128 with a plurality of traces 130 disposed on the top surface 126. As with the first exemplary embodiment, the plurality of traces 130 comprise a silver paste and the substrate 124 comprises a polyethylene terephthalate (PET) film. Nevertheless, it should be understood that the plurality of traces 130 could instead comprise nano copper traces 130 or other conductive materials. Similarly, the flexible substrate 124 may alternatively comprise other materials besides or in addition to PET (e.g., polyimide, polyester film, and polyether ether ketone).

In contrast to the first exemplary embodiment of the flexible light emitting system 20, the second exemplary embodiment of the flexible light emitting system 120 further includes a carrier layer 140 extending along the bottom surface 128 of the flexible printed circuit layer 122 to provide a base for attachments (e.g., to the interior or exterior of a motor vehicle) and an electrical connector housing (e.g., to connect to an electrical energy source on a vehicle).

The flexible printed circuit layer 122 includes a plurality of micro light emitting diodes 132 disposed on the top surface 126 and soldered to the plurality of traces 130 to provide light. As with the first exemplary embodiment, the plurality of micro light emitting diodes 132 may be different colors, such as, but not limited to, red micro LEDs, blue micro LEDs and amber micro LEDs.

Also similar to the first exemplary embodiment, an elastic interlayer film 134 extends over the top surface 126 of the flexible printed circuit layer 122 for protection of the plurality of micro light emitting diodes 132 and the plurality of traces 130. Again, the elastic interlayer film 134 can comprise ethylene-vinyl acetate (EVA) copolymer, for example.

A diffuser layer 136 extends over the elastic interlayer film 134 opposite the flexible printed circuit layer 122 to diffuse the light from the plurality of micro light emitting diodes 132. As with the first exemplary embodiment of the flexible light emitting system 20, the diffuser layer 136 of the second exemplary embodiment of the flexible light emitting system 120 is adapted to be printed upon to provide an eye pleasing unlit appearance.

As compared to the first exemplary embodiment of the flexible light emitting system 20, no optically transparent material layer 38 extends between the elastic interlayer film 134 and the diffuser layer 136 of the second exemplary embodiment of the flexible light emitting system 120. Instead, the elastic interlayer film 134 and the diffuser layer 136 extend in a spaced relationship to one another a distance D to define an air space 142 therebetween (e.g., preferably 2-10 mm between the elastic interlayer film 134 and the diffuser layer 136). This air space 142 extending the distance D functions like the optically transparent material layer 38 of the first exemplary embodiment to provide a uniform light appearance from the plurality of micro light emitting diodes 132. The diffuser layer 136 can include or be comprised of a lens 137 with a diffuser 139. Alternatively or in addition, the diffuser layer 136 can additionally include a Fresnel surface 141.

Both the first and second exemplary embodiments of the flexible light emitting systems 20, 120 provide a three-dimensional, flexible, uniform light stack that can be manufactured using high speed direct transfer technology of micro LEDs 32, 132 onto flexible printed circuit layers 22, 122. Consequently, the disclosed flexible light emitting systems 20, 120 enable thinner, more efficient (electrical power and thermal), less expensive, robust lighting solutions compared to other known lighting solutions employing panels with light-emitting diodes (LEDs) disposed along the edges of the panel or side emitting LEDs. Thinner packaging, better performance for backlighting applications, and aesthetic design flexibility are therefore provided.

Clearly, changes may be made to what is described and illustrated herein without, however, departing from the scope defined in the accompanying claims. The flexible light emitting systems 20, 120 may be implemented as part of myriad interior and exterior lighting applications. In general, the disclosed flexible light emitting systems 20, 120 may be used also for other purposes, within a motor vehicle, or for different non-automotive lighting applications.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure. Those skilled in the art will recognize that concepts disclosed in association with an example flexible light emitting systems 20, 120 can likewise be implemented into many other systems to provide lighting.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The system or device may be otherwise oriented (rotated degrees or at other orientations) and the spatially relative descriptions used herein interpreted accordingly.

What is claimed is:

1. A flexible light emitting system, comprising:
a flexible printed circuit layer having a substrate with a top surface and a bottom surface;
a plurality of traces disposed on said top surface;
said flexible printed circuit layer including a plurality of micro light emitting diodes disposed on said top surface and electrically coupled to said plurality of traces to provide light;
an elastic interlayer film extending over said top surface of said flexible printed circuit layer for protection of said plurality of micro light emitting diodes and said plurality of traces; and
a diffuser layer extending over said elastic interlayer film opposite said flexible printed circuit layer to diffuse the light from said plurality of micro light emitting diodes.

2. The flexible light emitting system as set forth in claim 1, wherein said elastic interlayer film and said diffuser layer extend in a spaced relationship to one another to define an air space extending a distance therebetween and provide a uniform light appearance from said plurality of micro light emitting diodes.

3. The flexible light emitting system as set forth in claim 2, wherein said distance is between 2 and 10 millimeters.

4. The flexible light emitting system as set forth in claim 1, further including an optically transparent material layer having an thickness and extending between said elastic interlayer film and said diffuser layer to provide a uniform light appearance from said plurality of micro light emitting diodes.

5. The flexible light emitting system as set forth in claim 4, wherein said thickness is between 2 and 10 millimeters.

6. The flexible light emitting system as set forth in claim 1, wherein said plurality of traces comprise a silver paste.

7. The flexible light emitting system as set forth in claim 1, wherein said plurality of traces comprise nano copper traces.

8. The flexible light emitting system as set forth in claim 1, wherein said substrate comprises a polyethylene terephthalate film.

9. The flexible light emitting system as set forth in claim 1, further including a carrier layer extending along said bottom surface of said flexible printed circuit layer to provide a base for attachments and an electrical connector.

10. The flexible light emitting system as set forth in claim 1, wherein said plurality of light emitting diodes are different colors.

11. The flexible light emitting system as set forth in claim 1, wherein said diffuser layer includes a lens with a diffuser.

12. The flexible light emitting system as set forth in claim 1, wherein said diffuser layer includes a Fresnel surface.

13. The flexible light emitting system as set forth in claim 1, wherein said elastic interlayer film is constructed of ethylene-vinyl acetate copolymer.

14. The flexible light emitting system as set forth in claim 1, wherein said diffuser layer is adapted to be printed upon.

15. The flexible light emitting system as set forth in claim 1, wherein said substrate is formed of a material selected from the group consisting of polyimide, polyester film, and polyether ether ketone.

16. The flexible light emitting system as set forth in claim 1, wherein said plurality of traces comprise printed silver circuitry.

17. The flexible light emitting system as set forth in claim 6, wherein said plurality of micro light emitting diodes are soldered to said plurality of traces.

18. The flexible light emitting system as set forth in claim 1, wherein said plurality of micro light emitting diodes include phosphor.

19. The flexible light emitting system as set forth in claim 18, wherein said wherein said plurality of micro light emitting diodes are blue micro light emitting diodes and emit white light with said phosphor.

20. The flexible light emitting system as set forth in claim 4, wherein said optically transparent material layer is ultraviolet stable.
